(19) United States
(12) Patent Application Publication
(10) Pub. No.: US 2025/0221213 A1
(43) Pub. Date: Jul. 3, 2025

(54) TRANSPARENT DISPLAY DEVICE

(71) Applicant: LG Display Co., Ltd., Seoul (KR)

(72) Inventor: Intae Ko, Paju-si (KR)

(73) Assignee: LG Display Co., Ltd., Seoul (KR)

(21) Appl. No.: 18/988,499

(22) Filed: Dec. 19, 2024

(30) Foreign Application Priority Data
Dec. 28, 2023 (KR) 10-2023-0195616

(51) Int. Cl. H10K 59/131; H10K 59/88

(52) U.S. Cl. CPC H10K 59/131; H10K 59/88

(57) ABSTRACT

A transparent display device can include a display area having a plurality of pixel blocks disposed therein and configured to display an image, a bezel area disposed at one or more sides of the display area, and a plurality of mesh blocks disposed in the bezel area. Each of the plurality of mesh blocks can include a mesh power line having a mesh shape. Each of the plurality of pixel blocks includes a first transmissive area configured to transmit external light, and each of the plurality of mesh blocks includes a second transmissive area configured to transmit external light.

### CROSS-REFERENCE TO RELATED APPLICATIONS

This application claims priority to Korean Patent Application No. 10-2023-0195616, filed in the Republic of Korea on Dec. 28, 2023, the entirety of which is hereby expressly incorporated by reference into the present application.

### BACKGROUND

### Technical Field

The present disclosure relates to a transparent display device.

### Discussion of the Related Art

With advancement in information-oriented societies, demands for display devices that display an image have increased in various forms. Various types of display devices such as a liquid crystal display (LCD) device, a plasma display panel (PDP) device, a Quantum dot Light Emitting Display (QLED), and an organic light emitting display (OLED) device have been widely utilized.

In recent years, there has been active research on display devices that allow user to view objects or images located on the rear surface of the display device. The transparent display device can include a display area where images are displayed and the display area can include a transmissive area that can transmit external light. In the transparent display device, a high light transmittance can be achieved in the display area through the transmissive area.

### BRIEF SUMMARY OF THE DISCLOSURE

The present disclosure is directed to providing a transparent display device, which substantially obviate one or more problems due to limitations and disadvantages of the related art.

An aspect of the present disclosure is directed to providing a transparent display device which can enhance a light transmittance.

Another aspect of the present disclosure is directed to providing a transparent display device which can stably supply power.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these and other advantages and in accordance with the purpose of the disclosure, as embodied and broadly described herein, there is provided a transparent display device including a display area having a plurality of pixel blocks disposed therein and configured to display an image, a bezel area disposed at one or more sides of the display area, and a plurality of mesh blocks disposed in the bezel area, where each of the plurality of mesh blocks includes a mesh power line having a mesh shape. Each of the plurality of pixel blocks includes a first transmissive area configured to transmit external light, and each of the plurality of mesh blocks includes a second transmissive area configured to transmit external light.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

FIG. 1 is a plan view schematically illustrating a transparent display device according to one or more embodiments of the present disclosure.

FIG. 2 is an enlarged view of a region A of FIG. 1.

FIG. 3 is a diagram illustrating an example of a pixel block illustrated in FIG. 2.

FIG. 4 is a circuit diagram illustrating an example of a subpixel included in the pixel block illustrated in FIG. 3.

FIG. 5 is a cross-sectional view illustrating an example of elements disposed in a transmissive area and a non-transmissive area of FIG. 3.

FIG. 6 is a diagram illustrating an example of a mesh block illustrated in FIG. 2.

FIG. 7 is a cross-sectional view illustrating an example taken along line I-I′ of FIG. 6.

FIG. 8 is a cross-sectional view illustrating an example taken along line II-II′ of FIG. 6.

FIG. 9 is a cross-sectional view illustrating an example taken along line III-III′ of FIG. 6.

FIG. 10 is a cross-sectional view illustrating an example taken along line IV-IV′ of FIG. 6.

FIG. 11 is a diagram illustrating an example where a mesh block is disposed in a transparent display panel according to an embodiment of the present disclosure.

FIG. 12 is a diagram illustrating an example of a first column line and a second column line disposed in a region B of FIG. 11.

FIG. 13 is a graph showing a relationship between the number of pixel blocks included in a first column line and the number of mesh blocks included in a second column line.

FIG. 14 is a diagram illustrating an example where a transparent display device according to an embodiment of the present disclosure is applied to a vehicle.

### DETAILED DESCRIPTION OF THE EMBODIMENTS

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by scopes of claims.

A shape, a size, a ratio, an angle, and a number disclosed in the drawings for describing embodiments of the present disclosure are merely an example, and thus the present disclosure is not limited to the illustrated details. Like reference numerals refer to like elements throughout. In the following description, when the detailed description of the relevant known technology is determined to unnecessarily obscure the important point of the present disclosure, the detailed description will be omitted. In a case where “comprise,” “have,” and “include” described in the present disclosure are used, another part can be added unless “only” is used. The terms of a singular form can include plural forms unless referred to the contrary. Further, the term “can” fully encompasses all the meanings and coverages of the term “may.”

In construing an element, the element is construed as including an error range although there is no explicit description.

In describing a positional relationship, for example, when a position relation between two parts is described as “on”, “over”, “under”, and “next”, one or more other parts can be disposed between the two parts unless “just” or “direct” is used.

In describing a temporal relationship, for example, when a temporal precedence relationship is described such as “after”, “following”, “next”, “before”, etc., it can include cases that are not consecutive unless “immediately” or “directly” are used.

It will be understood that, although the terms “first,” “second,” etc. can be used herein to describe various elements, these elements should not be limited by these terms. These terms are only used to distinguish one element from another and may not necessarily define order or sequence. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or totally coupled to or combined with each other, and can be variously inter-operated and driven technically. The embodiments of the present disclosure can be carried out independently from each other or can be carried out together with a co-dependent relationship.

Hereinafter, with reference to the accompanying drawings, one example of a display device according to the present disclosure is described. In assigning reference numerals to the components in each drawing, the same component can have the same numeral as far as possible, even if it is shown in different drawings. In addition, when the detailed description of the relevant known technology is determined to unnecessarily obscure the important point of the present disclosure, the detailed description will be omitted.

Hereinafter, embodiments of the present disclosure will be described in detail with reference to the accompanying drawings. All the components of each display device/apparatus according to all embodiments of the present disclosure are operatively coupled and configured.

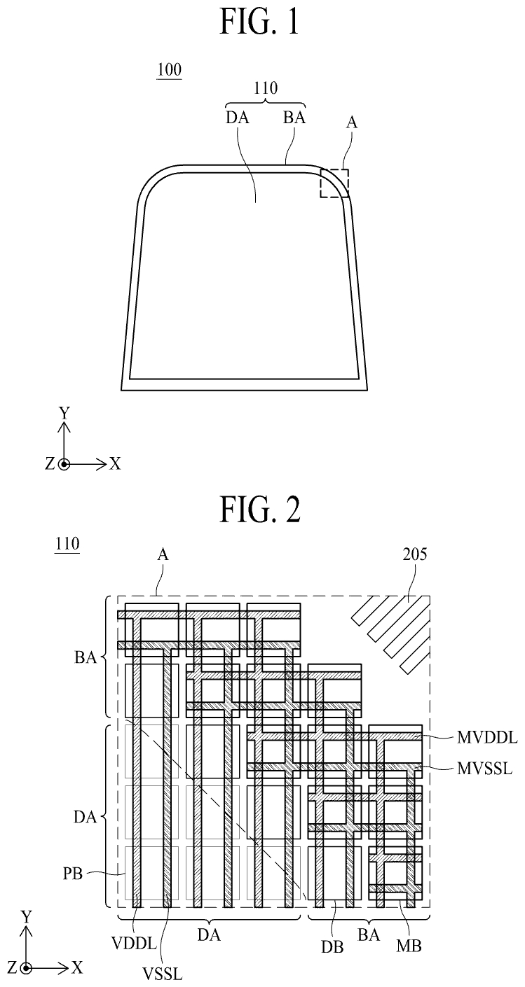

FIG. 1 is a plan view schematically illustrating a transparent display device 100 according to an embodiment of the present disclosure, and FIG. 2 is an enlarged view of a region A of FIG. 1.

Herein, an X axis can represent a direction parallel to a scan line, a Y axis can represent a direction parallel to a data line, and a Z axis can represent a height of a transparent display device 100.

The transparent display device 100 according to an embodiment of the present disclosure can be mainly described as being implemented as an organic light emitting display, but is not limited thereto and can be implemented as a liquid crystal display (LCD), a plasma display panel (PDP), a quantum dot light emitting display (QLED), or an electrophoresis display.

Referring to FIGS. 1 and 2, the transparent display device 100 according to an embodiment of the present disclosure can include a transparent display panel 110. The transparent display panel 110 can be divided into a display area DA where pixels are provided to display an image and a bezel area BA which does not display an image.

A plurality of pixel blocks PB can be disposed in the display area DA.

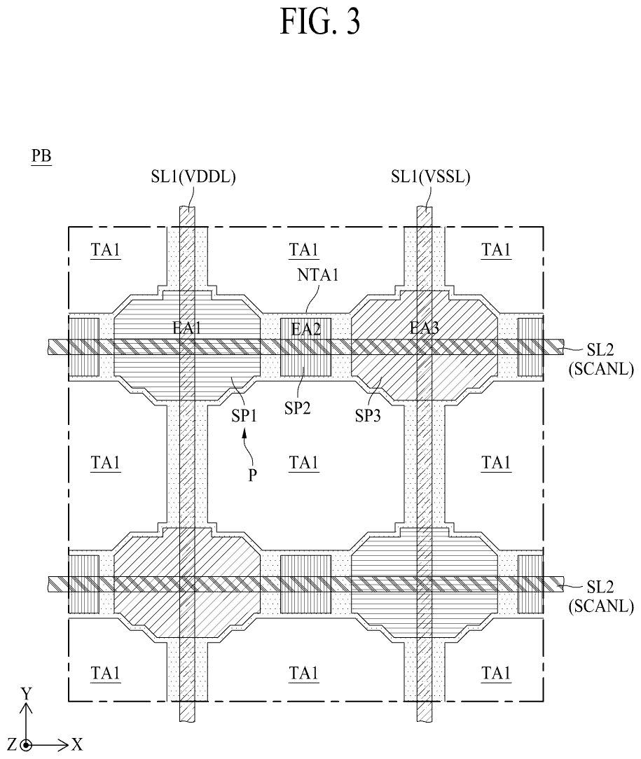

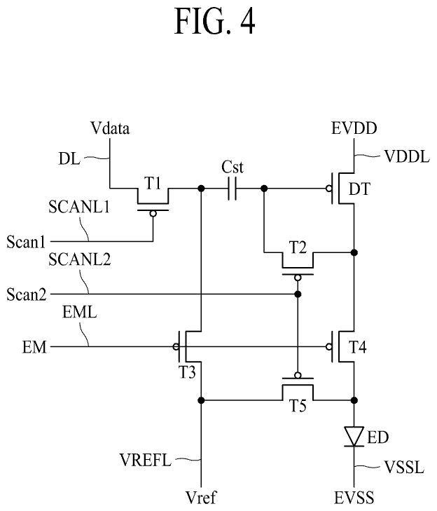

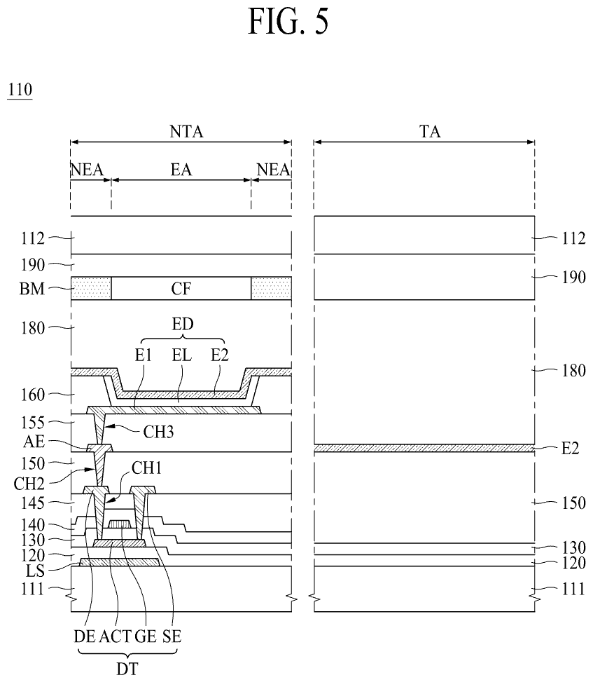

FIG. 3 is a diagram illustrating an example of a pixel block illustrated in FIG. 2. FIG. 4 is a circuit diagram illustrating an example of a subpixel included in the pixel block illustrated in FIG. 3. FIG. 5 is a cross-sectional view illustrating an example of elements disposed in a transmissive area and a non-transmissive area of FIG. 3.

Referring to FIGS. 3 to 5, each of the plurality of pixel blocks PB, as illustrated in FIG. 3, can include a first area NTA1 where a plurality of subpixels SP1 to SP3 are disposed and a second area TA1 where a plurality of subpixels SP1 to SP3 are not disposed. The first area NTA1 can be a first non-transmissive area which does not transmit the most of light incident from the outside, and the second area TA1 can be a first transmissive area which transmits the most of light incident from the outside.

For example, the first transmissive area TA1 can be an area where a light transmittance is greater than x %, and the first non-transmissive area NTA1 can be an area where a light transmittance is less than 3%. Here, a can be a value which is greater than B. The transparent display panel 110 can enable a thing or a background disposed at a rear surface of the transparent display panel 110 to be seen, based on a plurality of first transmissive areas TA1.

The plurality of subpixels SP1 to SP3, a plurality of circuit devices, and a plurality of signal lines SL1 and SL2 can be disposed in the first non-transmissive area NTA1 and cannot transmit light incident from the outside.

The plurality of signal lines can include first signal lines SL1 and second signal lines SL2. The first signal lines SL1 can extend in a first direction (for example, a Y-axis direction) in the first non-transmissive area NTA1. The first signal lines SL1 can have a rectilinear shape. The first signal lines SL1 can include a pixel power line VDDL, a data line, and a common power line VSSL. In an embodiment, the first signal lines SL1 can further include a reference line.

The pixel power line VDDL can transfer a first power to a driving transistor of each of the plurality of subpixels SP1 to SP3. The common power line VSSL can transfer a second power to a cathode electrode of each of the plurality of subpixels SP1 to SP3. In this case, the second power can be a common power which is supplied to the plurality of subpixels SP1 to SP3 in common. Also, the common power line VSSL can be spaced apart from the pixel power line VDDL with a transmissive area TA therebetween. One pixel power line VDDL or one common power line VSSL can be disposed between transmissive areas TA adjacent to each other in a second direction (for example, an X-axis direction).

The reference line can transfer an initialization voltage (or a reference voltage) to the driving transistor of each of the plurality of subpixels SP1 to SP3. Data lines can respectively transfer data voltages to the plurality of subpixels SP1 to SP3.

The second signal lines SL2 can extend in the second direction (for example, the X-axis direction) in the first non-transmissive area NTA1. The second signal line SL2 can include a scan line SCANL. The scan line SCANL can be provided as one or in plurality between transmissive areas TA adjacent to each other in the first direction (for example, the Y-axis direction). The scan line SCANL can include a first scan line and a second scan line. The second signal line SL2 can further include an emission control line. The scan line SCANL can transfer a scan signal to the subpixels SP1 to SP3.

Each of the subpixels SP1 to SP3 can be included in the first non-transmissive area NTA1 and can emit light to display an image. An emission area EA can correspond to an area, emitting light, of each of the subpixels SP1 to SP3.

The subpixels SP1 to SP3 can each be one of a first subpixel SP1 emitting light of a first color, a second subpixel SP2 emitting light of a second color, and a third subpixel SP3 emitting light of a third color, but are not limited thereto. A unit pixel P can include two or more subpixels SP1 to SP3. For example, the unit pixel P can include the first subpixel SP1, the second subpixel SP2, and the third subpixel SP3. As another example, one unit pixel P can include the first subpixel SP1 and the second subpixel SP2, and the other unit pixel P can include the second subpixel SP2 and the third subpixel SP3. Each pixel P can further include a fourth subpixel SP4 which emits white light.

The first subpixel SP1 can include a first emission area EA1 which emits light of a first color, the second subpixel SP2 can include a second emission area EA2 which emits light of a second color, and the third subpixel SP3 can include a third emission area EA3 which emits light of a third color. However, embodiments of the present disclosure are not limited thereto. Each pixel P can further include the fourth subpixel SP4 which emits white light.

For example, the first to third emission areas EA1 to EA3 can emit lights of different colors. For example, the first emission area EA1 can emit blue light, the second emission area EA2 can emit red light, and the third emission area EA3 can emit green light. An arrangement order of subpixels SP1 to SP3 can be variously changed.

The subpixels SP1 to SP3 can be disposed to overlap at least one of the first signal line SL1 and the second signal line SL2. The first to third subpixels SP1 to SP3 can be disposed in a region where the first signal line SL1 overlaps the second signal line SL2.

In detail, each of the first subpixel SP1 and the third subpixel SP3 can be disposed in a region where one of the pixel power line VDDL and the common power line VSSL overlaps the second signal line SL2. For example, the first subpixel SP1 can be disposed in a region where the pixel power line VDDL overlaps the second signal line SL2, and the third subpixel SP3 can be disposed in a region where the common power line VSSL overlaps the second signal line SL2.

The first subpixel SP1 and the third subpixel SP3 can be arranged alternately along the pixel power line VDDL and can be arranged alternately along the common power line VSSL. In this case, in a first horizontal line, the third subpixel SP3 can be disposed in a region where the common power line VSSL overlaps the second signal line SL2, and the first subpixel SP1 can be disposed in a region where the pixel power line VDDL overlaps the second signal line SL2. Also, in a second horizontal line disposed next thereto, the third subpixel SP3 can be disposed in a region where the pixel power line VDDL overlaps the second signal line SL2, and the first subpixel SP1 can be disposed in a region where the common power line VSSL overlaps the second signal line SL2.

The second subpixel SP2 can be disposed between the first subpixel SP1 and the third subpixel SP3. The second subpixel SP2 can be disposed in a region where the second signal line SL2 is provided, between adjacent first signal lines SL1. The second subpixel SP2 can be disposed in a region where the second signal line SL2 is provided, between the pixel power line VDDL and the common power line VSSL disposed adjacent to each other.

Each of the first subpixel SP1, the second subpixel SP2, and the third subpixel SP3 can include a circuit device and a light emitting device. Referring to FIG. 4, each of the subpixels SP1 to SP3 can include a pixel circuit which includes a plurality of transistors DT and T1 to T5 and a light emitting device ED.

The pixel circuit illustrated in FIG. 4 can include five switching transistors T1 to T5, a driving transistor DT, a storage capacitor Cst, and a light emitting device ED, but is not limited thereto.

Each of the transistors DT and T1 to T5 of each of the subpixels SP1 to SP3 can include a gate electrode, a source electrode, and a drain electrode. The source electrode and the drain electrode cannot be fixed and can be changed based on a direction of a voltage and a current applied to the gate electrode, and thus, one of the source electrode and the drain electrode can be referred to as a first electrode, and the other can be referred to as a second electrode. The transistors DT and T1 to T5 of each of the subpixels SP1 to SP3 can use at least one of a polysilicon semiconductor, an amorphous silicon semiconductor, and an oxide semiconductor. The transistors can be a P type or an N type, or can be a combination of a P type and an N type.

A first electrode of a driving transistor DT can be connected to the pixel power line VDDL which transfers a first source voltage EVDD. A second electrode of the driving transistor DT can drive the light emitting device ED through a fourth switching transistor T4. The driving transistor DT can control a driving current, based on a driving voltage of the storage capacitor Cst. Accordingly, the driving transistor DT can control an emission intensity of the light emitting device ED.

The storage capacitor Cst can be charged with a driving voltage Vg corresponding to a data voltage Vdata. The storage capacitor Cst can supply a charged driving voltage Vg to the driving transistor DT.

A first switching transistor T1 can be turned on or off in response to a first scan signal Scan1 supplied to a first scan line SCANL1. The first switching transistor T1 can supply the data voltage Vdata, supplied through a data line DL, to a first electrode of the storage capacitor Cst in response to a gate on voltage of the first scan signal Scan1.

Second and fifth switching transistors T2 and T5 can be turned on or off in response to a second scan signal Scan2 supplied to a second scan line SCANL2. The second switching transistor T2 can connect the second electrode and a gate electrode of the driving transistor DT with each other to connect the driving transistor DT in a diode structure, in response to a gate on voltage of the second scan signal Scan2. The second switching transistor T2 can charge a threshold voltage Vth of the driving transistor DT in the storage capacitor Cst to compensate for the driving transistor DT. Accordingly, the storage capacitor Cst can be charged with a data voltage “Vdata+Vth” obtained through the compensation of the threshold voltage Vth of the driving transistor DT.

The fifth switching transistor T5 can supply an initialization voltage Vref (or a reference voltage), supplied through an initialization voltage line VREFL, to an anode electrode of the light emitting device ED in response to a gate on voltage of the second scan signal Scan2.

Third and fourth switching transistors T3 and T4 can be turned on or off in response to an emission control signal EM supplied to the emission control line EML. The third switching transistor T3 can supply the initialization voltage Vref (or the reference voltage), supplied through the initialization voltage line VREFL, to the first electrode of the storage capacitor Cst in response to a gate on voltage of the emission control signal EM.

The fourth switching transistor T4 can connect the driving transistor DT to the light emitting device ED in response to a gate on voltage of the emission control signal EM. The light emitting device ED can include an anode electrode, a cathode electrode supplied with a second source voltage EVSS through the common power line VSSL, and an emission layer between the anode electrode and the cathode electrode. When a driving current is supplied from the driving transistor DT through the fourth switching transistor T4, an electron from the cathode electrode can be injected into the emission layer, a hole from the anode electrode can be injected into an organic emission layer, and a fluorescent or phosphorescent material can emit light, based on a recombination of the electron and the hole in the emission layer, and thus, the light emitting device ED can emit light having brightness proportional to a current value of the driving current.

Hereinafter, elements disposed in the first non-transmissive area NTA1 and the first transmissive area TA1 will be described in more detail with reference to FIG. 5.

Referring to FIG. 5, the transparent display panel 110 according to an embodiment of the present disclosure can include a first substrate 111 and a second substrate 112 facing each other, and a circuit device, the light emitting device ED, an encapsulation layer 180, a color filter CF, and a black matrix BM can be disposed between the first substrate 111 and the second substrate 112.

The circuit device can include various signal lines, a thin film transistor (TFT), and a capacitor. The signal lines can include pixel power lines, common power lines, scan lines, and data lines, and the TFT can include a switching transistor and the driving transistor DT. The switching transistor can be turned on based on a scan signal supplied to a scan line and can charge a data voltage, supplied through the data line, in the capacitor.

The driving transistor DT can be turned on based on a data voltage charged in the storage capacitor Cst (see FIG. 4) and can generate a data current from power supplied through the pixel power line VDDL (see FIG. 4) to supply the data current to a first electrode E1 of each of the subpixels SP1 to SP3. The driving transistor DT can include an active layer ACT, a gate electrode GE, a source electrode SE, and a drain electrode DE.

In detail, a light blocking layer LS can be provided on the first substrate 111. The light blocking layer LS can be provided to overlap a region where the driving transistor DT is formed and can block external light incident on the active layer ACT of the driving transistor DT. Also, the light blocking layer LS can be provided to overlap a region where other transistors (for example, the switching transistors T1 to T5 (see FIG. 4)) are formed and can block external light incident on an active layer of each of the switching transistors T1 to T5 (see FIG. 4).

The transparent display panel 110 can be much used in an environment which is exposed at the outside instead of the inside thereof. A time for which the transparent display panel 110 is exposed to external light can increase, and thus, a characteristic of a circuit device such as the transistors DT and T1 to T5 can be changed. Due to a change in characteristic of the circuit device, the transparent display panel 110 can decrease in luminance, and a screen can be darkened.

In the transparent display panel 110 according to an embodiment of the present disclosure, the light blocking layer LS can be disposed under the transistors DT and T1 to T5, and thus, can prevent external light from being incident on the transistors DT and T1 to T5. The transparent display panel 110 according to an embodiment of the present disclosure can prevent the characteristic of the transistors DT and T1 to T5 from being changed, and subpixels can maintain high luminance.

The light blocking layer LS can be formed of a single layer or a multilayer including one of molybdenum (Mo), aluminum (Al), chrome (Cr), gold (Au), titanium (Ti), nickel (Ni), neodymium (Nd), and copper (Cu), or an alloy thereof.

A buffer layer 120 can be provided on the light blocking layer LS. The buffer layer 120 can protect the transistors DT from water penetrating into the first substrate 111 vulnerable to water transmission. To this end, the buffer layer 120 can be included in the non-transmissive area NTA and the transmissive area TA. The buffer layer 120 can be formed of an inorganic layer, and for example, can be formed of silicon oxide (SiOx), silicon nitride (SiNx), or a multilayer thereof.

The active layer ACT of the driving transistor DT can be provided on the buffer layer 120. The active layer ACT of the driving transistor DT can include a silicon-based semiconductor material or an oxide-based semiconductor material.

A gate insulation layer 130 can be provided on the active layer ACT of the driving transistor DT. The gate insulation layer 130 can be included in the non-transmissive area NTA and the transmissive area TA. The gate insulation layer 130 can be formed of an inorganic layer, and for example, can be formed of SiOx, SiNx, or a multilayer thereof.

A gate electrode GE of the driving transistor DT can be provided on the gate insulation layer 130. The gate electrode GE of the driving transistor DT can be formed of a single layer or a multilayer including one of Mo, Al, Cr, Au, T1, Ni, Nd, and Cu, or an alloy thereof.

A first interlayer insulation layer 140 and a second interlayer insulation layer 145 can be provided on the gate electrode GE of the driving transistor DT. To increase a light transmittance of the first transmissive area TA1, the first interlayer insulation layer 140 and the second interlayer insulation layer 145 can be included in only the first non-transmissive area NTA1 and cannot be included in the first transmissive area TA1. Each of the first interlayer insulation layer 140 and the second interlayer insulation layer 145 can be formed of an inorganic layer, and for example, can be formed of SiOx, SiNx, or a multilayer thereof.

A source electrode SE and a drain electrode DE of the driving transistor DT can be provided on the second interlayer insulation layer 145. Each of the source electrode SE and the drain electrode DE of the driving transistor DT can be connected to the active layer ACT of the driving transistor DT through a first contact hole CH1 passing through the first interlayer insulation layer 140 and the second interlayer insulation layer 145. The source electrode SE and the drain electrode DE of the driving transistor DT can be formed of a single layer or a multilayer including one of Mo, Al, Cr, Au, Ti, Ni, Nd, and Cu, or an alloy thereof.

A first planarization layer 150 can be provided on the source electrode SE and the drain electrode DE of the driving transistor DT so as to planarize a step height caused by the driving transistor DT. The first planarization layer 150 can be formed of an organic layer such as acryl resin, epoxy resin, phenolic resin, polyamide resin, or polyimide resin.

An auxiliary electrode AE can be provided on the first planarization layer 150. The auxiliary electrode AE can be connected to one of the source electrode SE and the drain electrode DE of the driving transistor DT through a second contact hole CH2 passing through the first planarization layer 150. The auxiliary electrode AE can be formed of a single layer or a multilayer including one of Mo, Al, Cr, Au, Ti, Ni, Nd, and Cu, or an alloy thereof.

A second planarization layer 155 can be provided on the auxiliary electrode AE. The second planarization layer (PLN2) 155 can be formed of an organic layer such as acryl resin, epoxy resin, phenolic resin, polyamide resin, or polyimide resin.

At least one of the first planarization layer 150 and the second planarization layer 155 can be provided in the first non-transmissive area NTA1 and cannot be provided in at least a portion of the first transmissive area TA1.

In the transparent display panel 110 according to an embodiment of the present disclosure, at least one of the first planarization layer 150 and the second planarization layer 155 cannot be provided in the first transmissive area TA1, and thus, a light transmittance of the first transmissive area TA1 can be enhanced.

Light emitting devices ED each including a first electrode E1, an emission layer EL, and a second electrode E2 and a bank 160 can be provided on the second planarization layer 155.

The first electrode E1 can be provided on the second planarization layer 155 and can be electrically connected to the driving transistor DT. In detail, the first electrode E1 can be connected to the auxiliary electrode AE through a third contact hole CH3 passing through the second planarization layer 155. Also, the auxiliary electrode AE can be connected to one of the source electrode SE and the drain electrode DE of the driving transistor DT through the second contact hole CH2, and the first electrode E1 can be connected to one of the source electrode SE and the drain electrode DE of the driving transistor DT through the auxiliary electrode AE.

The first electrode E1 can be included in each of the subpixels SP1 to SP3 and cannot be included in the transmissive area TA. The bank 160 can be provided between adjacent first electrodes E1, and thus, the adjacent first electrodes E1 can be electrically insulated from each other.

The first electrode E1 can include a metal material having a high reflectance such as a stack structure (Ti/Al/Ti) of aluminum and titanium, a stack structure (ITO/AI/ITO) of aluminum and indium tin oxide (ITO), an Ag alloy, a stack structure (ITO/Ag alloy/ITO) of Ag alloy and ITO, a MoTi alloy, and a stack structure (ITO/MoTi alloy/ITO) of MoTi alloy and ITO. The Ag alloy can be an alloy of Ag, palladium (Pd), and Cu. The MoTi alloy can be an alloy of Mo and Ti. The first electrode E1 can be an anode electrode.

The bank 160 can be provided on the second planarization layer 155. Also, the bank 160 can be formed to cover an edge of the first electrode E1 and expose a portion of the first electrode E1. Accordingly, the bank 160 can solve a problem where emission efficiency is reduced because current concentrate on an end of the first electrode E1.

The bank 160 can define emission areas (EA) EA1 to EA3 of the subpixels SP1 to SP3. Each of the emission areas (EA) EA1 to EA3 of the subpixels SP1 to SP3 can represent an area where the first electrode E1, the emission layer EL, and the second electrode E2 are sequentially stacked, and thus, a hole from the first electrode E1 and an electron from the second electrode E2 can be combined with each other in the emission layer EL to emit light. In this case, an area where the bank 160 is formed cannot emit light and can thus be a non-emission area NEA, and an area where the bank 160 is not formed and the first electrode E1 is exposed can be the emission areas (EA) EA1 to EA3. The bank 160 can be provided in the first non-transmissive area NTA1 and cannot be provided in at least a portion of the first transmissive area TA1.

The bank 160 can be formed of an organic layer such as an acryl-based material, an epoxy-based material, a phenolic-based material, a polyamide-based material, or a polyimide-based material.

The emission layer EL can be disposed on the first electrode E1. The emission layer EL can include an emission material layer (EML) including a light emitting material. The light emitting material can include an organic material, an inorganic material, or a hybrid material. The emission layer EL can have a multi-layer structure. For example, the emission layer EL can further include at least one of a hole injection layer (HIL), a hole transport layer (HTL), an electron transport layer (ETL), and an electron injection layer (EIL). In this case, when a voltage is applied to the first electrode E1 and the second electrode E2, a hole and an electron can respectively move to an emission material layer through a hole transport layer and an electron transport layer, and can be combined with each other in the emission material layer to emit light.

In an embodiment, the emission layer EL can be a common layer which is formed in the subpixels SP1 to SP3 in common. In this case, the emission layer EL can be a white emission layer which emits white light. Here, the emission layer EL can be formed in a non-emission area NEA between the subpixels SP1 to SP3, in addition to the subpixels SP1 to SP3. The emission layer EL can be continuously formed in the subpixels SP1 to SP3 and between the subpixels SP1 to SP3. Also, the emission layer EL can be provided in the first transmissive area TA1 as well as the first non-transmissive area NTA1 including the emission areas EA1 to EA3 and the non-emission area NEA, but is not limited thereto. The emission layer EL can be patterned and formed in only the first non-transmissive area NTA1 including the emission areas EA1 to EA3 and the non-emission area NEA.

In another embodiment, as illustrated in FIG. 5, in the emission layer EL, an emission material layer can be formed in each of the subpixels SP1 to SP3. For example, a green emission layer emitting green light can be formed in the first subpixel SP1, a red emission layer emitting red light can be formed in the second subpixel SP2, and a blue emission layer emitting blue light can be formed in the third subpixel SP3. In this case, the emission material layer of the emission layer EL cannot be formed in the first transmissive area TA1. A hole injection layer (HIL), a hole transport layer (HTL), an electron transport layer (ETL), and an electron injection layer (EIL) except the emission material layer can be formed in the subpixels SP1 to SP3 in common and can also be formed in the first transmissive area TA1.

The second electrode E2 can be disposed on the emission layer EL. The second electrode E2 can be a common layer which is formed in the subpixels SP1 to SP3 in common. The second electrode E2 can be formed in the non-emission area NEA between the subpixels SP1 to SP3, in addition to the emission areas (EA) EA1 to EA3. In this case, the emission layer EL can be a white emission layer which emits white light. The second electrode E2 can be continuously formed in the subpixels SP1 to SP3 and between the subpixels SP1 to SP3.

The second electrode E2 can include a transparent conductive material (TCO), such as ITO or indium zinc oxide (IZO) capable of transmitting light, or a semi-transmissive conductive material such as magnesium (Mg), Ag, or an alloy of Mg and Ag. In a case where the second electrode E2 includes a semi-transmissive conductive material, emission efficiency can be increased by a microcavity. The second electrode E2 can be a cathode electrode.

The encapsulation layer 180 can be provided on the light emitting devices ED. The encapsulation layer 180 can be formed on the second electrode E2 to cover the second electrode E2. The encapsulation layer 180 can prevent oxygen or water from penetrating into the emission layer EL and the second electrode E2. To this end, the encapsulation layer 180 can include at least one inorganic layer and at least one organic layer. The encapsulation layer 180 can be formed in a structure where an inorganic layer and an organic layer are alternately stacked, but is not limited thereto.

A color filter CF can be provided on the encapsulation layer 180. The color filter CF can be patterned and formed in each of the subpixels SP1 to SP3. In detail, the color filter CF can include a first color filter, a second color filter, and a third color filter. The first color filter can be disposed to correspond to an emission area EA1 of the first subpixel SP1 and can be a blue color filter which transmits blue light. The second color filter can be disposed to correspond to an emission area EA2 of the second subpixel SP2 and can be a red color filter which transmits red light. The third color filter can be disposed to correspond to an emission area EA3 of the third subpixel SP3 and can be a green color filter which transmits green light.

A black matrix BM can be provided between color filters CF which are patterned and formed in each of the subpixels SP1 to SP3. The black matrix BM can be provided between the subpixels SP1 to SP3 and can prevent the occurrence of color mixture between adjacent subpixels SP1 to SP3. Also, the black matrix BM can prevent light incident from the outside from being reflected by a plurality of signal lines provided between the subpixels SP1 to SP3.

Moreover, the black matrix BM can be provided between the first transmissive area TA1 and a plurality of subpixels SP1 to SP3 and can prevent light, emitted from each of the plurality of subpixels SP1 to SP3, from traveling to the first transmissive area TA1. The black matrix BM can include a material which absorbs light, and for example, can include a black dye which absorbs all light of a visible light wavelength band.

The first substrate 111 including the color filter CF and the black matrix BM can be bonded to the second substrate 112 by a separate adhesive layer 190. In this case, the adhesive layer 190 can be an optically clear resin layer (OCR) or an optically clear adhesive film (OCA).

Referring again to FIG. 2, a plurality of dummy blocks DB, a plurality of mesh blocks MB, and at least one scan driver 205 can be provided in the bezel area BA. The scan driver 205 can be disposed outside the plurality of dummy blocks DB and the plurality of mesh blocks MB. The scan driver 205 can supply the scan signal to the scan line SCANL (see FIG. 3) included in the pixel block PB.

Each of the plurality of mesh blocks MB can include a mesh power line having a mesh shape.

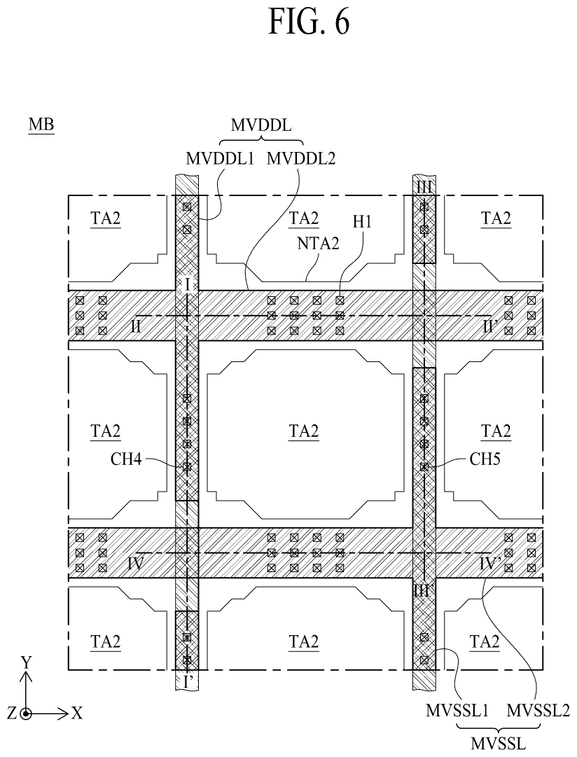

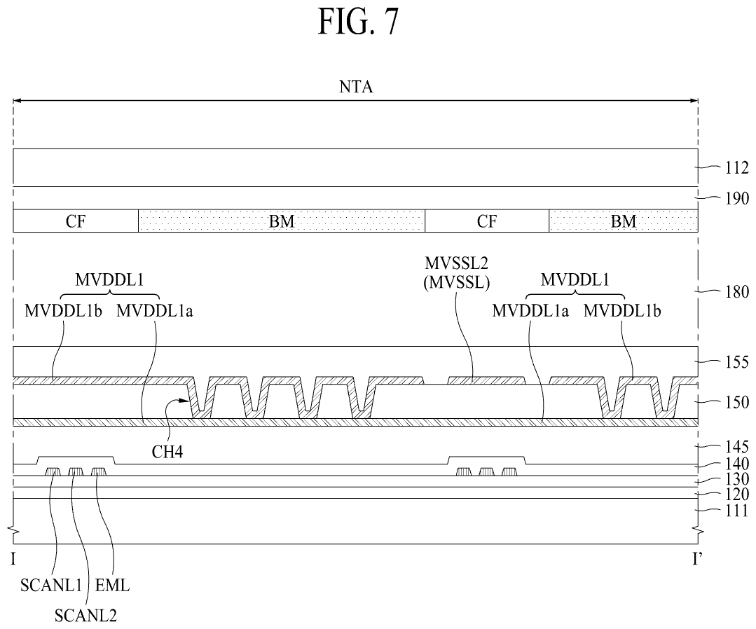

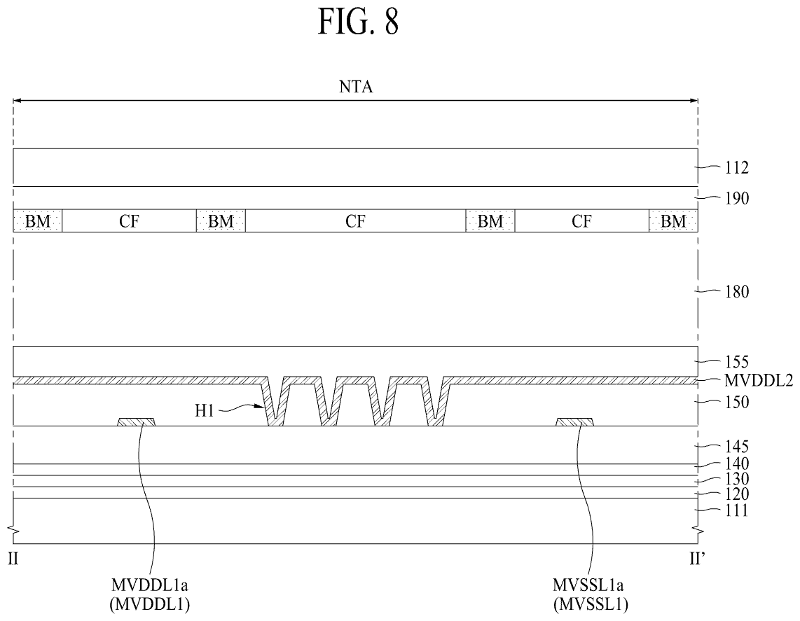

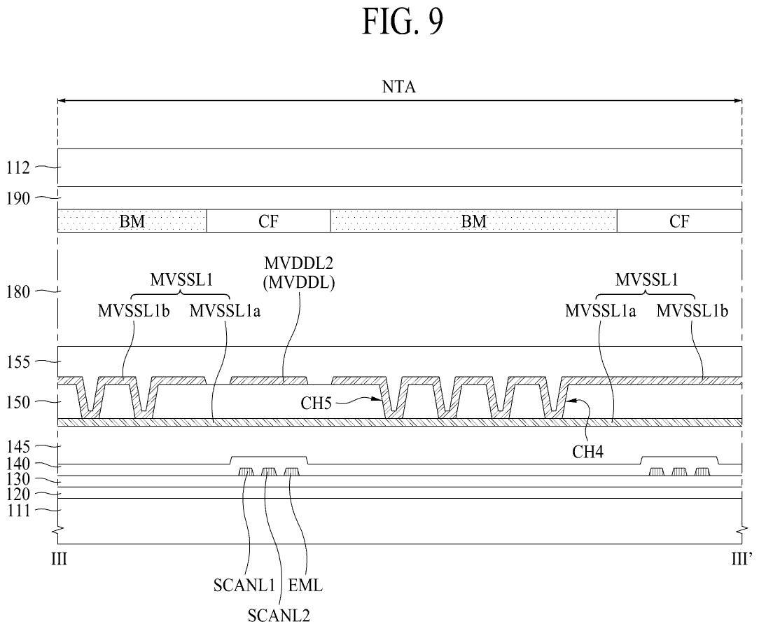

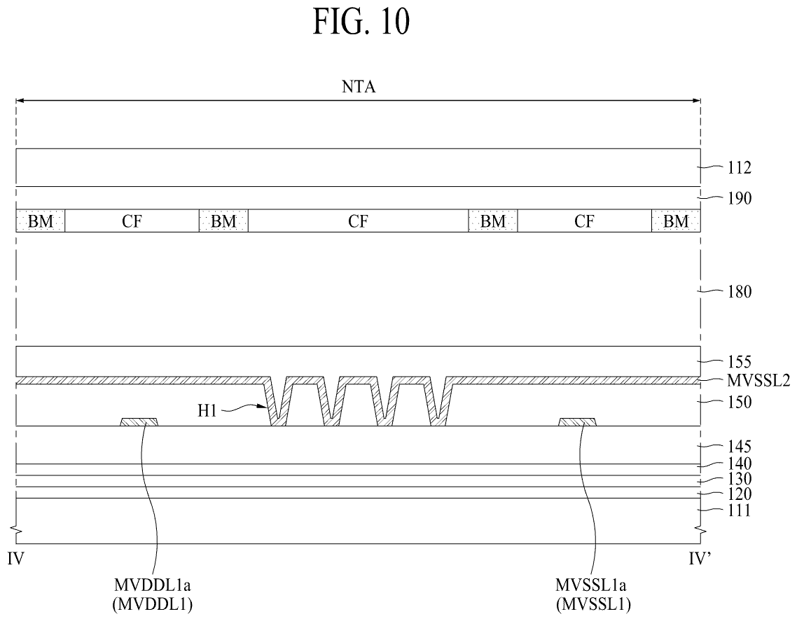

FIG. 6 is a diagram illustrating an example of the mesh block illustrated in FIG. 2. FIG. 7 is a cross-sectional view illustrating an example taken along line I-I′ of FIG. 6. FIG. 8 is a cross-sectional view illustrating an example taken along line II-II′ of FIG. 6. FIG. 9 is a cross-sectional view illustrating an example taken along line III-III′ of FIG. 6. FIG. 10 is a cross-sectional view illustrating an example taken along line IV-IV′ of FIG. 6.

Referring to FIGS. 6 to 10, each of the plurality of mesh blocks MB, as illustrated in FIG. 6, can include a first area NTA2 where a mesh power line is disposed and a second area TA2 where a mesh power line is not disposed. The first area NTA2 can be a second non-transmissive area which does not transmit the most of light incident from the outside, and the second area TA2 can be a second transmissive area which transmits the most of light incident from the outside.

For example, the second transmissive area TA2 can be an area where a light transmittance is greater than x %, and the second non-transmissive area NTA2 can be an area where a light transmittance is less than 3%. Here, a can be a value which is greater than B. The transparent display panel 110 can enable a thing or a background disposed at a rear surface of the transparent display panel 110 to be seen, based on a plurality of second transmissive areas TA2.

The mesh block MB can have the same size as that of the pixel block PB. Also, a ratio of a size of the second transmissive area TA2 in each mesh block MB to a size of an area of each mesh block MB can be equal to a ratio of a size of the first transmissive area TA1 in each pixel block PB to a size of an area of each pixel block PB. Accordingly, the transmissive display panel 110 according to an embodiment of the present disclosure can have the same light transmittance in a region where the pixel blocks PB are provided and a region where the mesh blocks MB are provided. The transmissive display panel 110 according to an embodiment of the present disclosure can increase a light transmittance of an entire panel and can prevent the occurrence of a sense of difference between a region where the pixel blocks PB are provided and a region where the mesh blocks MB are provided. For example, the transmissive display panel 110 according to an embodiment of the present disclosure can prevent the occurrence of a sense of difference between the display area DA and the bezel area BA.

A mesh pixel power line MVDDL and a mesh common power line MVSSL can be disposed in the second non-transmissive area NTA2 and cannot transmit light incident from the outside.

The mesh pixel power line MVDDL can include a first mesh pixel power line MVDDL1 and a second mesh pixel power line MVDDL2. The first mesh pixel power line MVDDL1 can extend in a first direction (for example, a Y-axis direction). The first mesh pixel power line MVDDL1, as illustrated in FIG. 7, can be configured with a plurality of layers. The first mesh pixel power line MVDDL1 can include a first layer MVDDLla and a second layer MVDDL1b. The first layer MVDDLla can be formed of the same material in the same layer as the source electrode SE (see FIG. 5) and the drain electrode DE (see FIG. 5) of the driving transistor DT (see FIG. 5) provided in the display area DA. The second layer MVDDL1b can be disposed on the first layer MVDDLla and can be formed of the same material in the same layer as the auxiliary electrode AE (see FIG. 5) provided in the display area DA. However, embodiments of the present disclosure are not limited thereto. In a case where the first layer MVDDLla and the second layer MVDDL1b are disposed in different layers with an insulation layer therebetween, the first layer MVDDLla and the second layer MVDDL1b can be disposed in any layer.

The second layer MVDDL1b of the first mesh pixel power line MVDDL1 can be connected to the first layer MVDDLla through a fourth contact hole CH4. The first layer MVDDLla and the second layer MVDDL1b of the first mesh pixel power line MVDDL1 can be electrically connected to each other. The second layer MVDDL1b can be connected to the first layer MVDDLla through a plurality of fourth contact holes CH4. Accordingly, in the transmissive display panel 110 according to an embodiment of the present disclosure, the first layer MVDDLla and the second layer MVDDL1b of the first mesh pixel power line MVDDL1 can be stably connected to each other without a contact defect.

Moreover, the first mesh pixel power line MVDDL1 can overlap the mesh common power line MVSSL in at least some regions. The first mesh pixel power line MVDDL1 can overlap the second mesh common power line MVSSL2 in at least some regions. Therefore, the first mesh pixel power line MVDDL1 can be formed of a single layer so that short circuit with the second mesh common power line MVSSL2 does not occur in a region overlapping the second mesh common power line MVSSL2. The first mesh pixel power line MVDDL1, as illustrated in FIG. 7, can be formed of a double layer including the first layer MVDDLla and the second layer MVDDL1b in a region which does not overlap the second mesh common power line MVSSL2 and can be formed of a single layer which is the first layer MVDDLla, in a region overlapping the second mesh common power line MVSSL2.

The second mesh pixel power line MVDDL2 can extend in a second direction (for example, an X-axis direction). The second mesh pixel power line MVDDL2, as illustrated in FIG. 8, can be formed of a single layer. The second mesh pixel power line MVDDL2 can be formed of the same material in the same layer as the auxiliary electrode AE (see FIG. 5) provided in the display area DA, but is not limited thereto.

The second mesh pixel power line MVDDL2 can be connected to the second layer MVDDL1b of the first mesh pixel power line MVDDL1. The second mesh pixel power line MVDDL2 can be electrically connected to the first mesh pixel power line MVDDL1.

In an embodiment, the second mesh pixel power line MVDDL2 can be provided along a plurality of first holes H1. A plurality of contact holes can be disposed in a region where the second subpixel SP2 is disposed, in the display area DA. Therefore, the plurality of first holes H1 can be formed in a region corresponding to the second subpixel SP2. Accordingly, the bezel area BA can have visibility which is similar to that of the display area DA.

The mesh common power line MVSSL can include a first mesh common power line MVSSL1 and a second mesh common power line MVSSL2. The first mesh common power line MVSSL1 can extend in the first direction (for example, the Y-axis direction). The first mesh common power line MVSSL1 can be disposed apart from the first mesh pixel power line MVDDL1 with the second transmissive area TA2 therebetween.

The first mesh common power line MVSSL1, as illustrated in FIG. 9, can be configured with a plurality of layers. The first mesh common power line MVSSL1 can include a first layer MVSSL1a and a second layer MVSSL1b. The first layer MVSSL1a can be formed of the same material in the same layer as the source electrode SE (see FIG. 5) and the drain electrode DE (see FIG. 5) of the driving transistor DT (see FIG. 5) provided in the display area DA. The second layer MVSSL1b can be disposed on the first layer MVSSL1a and can be formed of the same material in the same layer as the auxiliary electrode AE (see FIG. 5) provided in the display area DA. However, embodiments of the present disclosure are not limited thereto. In a case where the first layer MVSSL1a and the second layer MVSSL1b are disposed in different layers with an insulation layer therebetween, the first layer MVSSL1a and the second layer MVSSL1b can be disposed in any layer.

The second layer MVSSL1b of the first mesh common power line MVSSL1 can be connected to the first layer MVSSL1a through a fifth contact hole CH5. The first layer MVSSL1a and the second layer MVSSL1b of the first mesh common power line MVSSL1 can be electrically connected to each other. The second layer MVSSL1b can be connected to the first layer MVSSL1a through a plurality of fifth contact holes CH5. Accordingly, in the transmissive display panel 110 according to an embodiment of the present disclosure, the first layer MVSSL1a and the second layer MVSSL1b of the first mesh common power line MVSSL1 can be stably connected to each other without a contact defect.

Moreover, the first mesh common power line MVSSL1 can overlap the mesh pixel power line MVDDL in at least some regions. The first mesh common power line MVSSL1 can overlap the second mesh pixel power line MVDDL2 in at least some regions. Therefore, the first mesh common power line MVSSL1 can be formed of a single layer so that short circuit with the second mesh pixel power line MVDDL2 does not occur in a region overlapping the second mesh pixel power line MVDDL2. The first mesh common power line MVSSL1, as illustrated in FIG. 9, can be formed of a double layer including the first layer MVSSL1a and the second layer MVSSL1b in a region which does not overlap the second mesh pixel power line MVDDL2 and can be formed of a single layer which is the first layer MVSSL1a, in a region overlapping the second mesh pixel power line MVDDL2.

The second mesh common power line MVSSL2 can extend in the second direction (for example, the X-axis direction). The second mesh common power line MVSSL2 can be disposed apart from the second mesh pixel power line MVDDL2 with the second transmissive area TA2 therebetween.

The second mesh common power line MVSSL2, as illustrated in FIG. 10, can be configured with a single layer. The second mesh common power line MVSSL2 can be formed of the same material in the same layer as the auxiliary electrode AE (see FIG. 5) provided in the display area DA, but is not limited thereto.

The second mesh common power line MVSSL2 can be connected to the second layer MVSSL1b of the first mesh common power line MVSSL1. The second mesh common power line MVSSL2 can be electrically connected to the first mesh common power line MVSSL1.

In an embodiment, the second mesh common power line MVSSL2 can be provided along the plurality of first holes H1. A plurality of contact holes can be disposed in a region where the second subpixel SP2 is disposed, in the display area DA. Therefore, the plurality of first holes H1 can be formed in a region corresponding to the second subpixel SP2. Accordingly, the bezel area BA can have visibility which is similar to that of the display area DA.

The mesh pixel power line MVDDL of the mesh block MB can be electrically connected to the pixel power line VDDL of the pixel block PB. The mesh pixel power line MVDDL can be directly connected to the pixel power line VDDL of the pixel block PB. Alternatively, the mesh pixel power line MVDDL can be connected to the pixel power line VDDL of the pixel block PB through a dummy block DB.

In the mesh pixel power line MVDDL, the first mesh pixel power line MVDDL1 can extend in the first direction (for example, the Y-axis direction) toward the display area DA and can be connected to the pixel power line VDDL of the pixel block PB at one end thereof. In this case, the pixel power line VDDL of the pixel block PB cannot have a mesh structure, and thus, in the mesh pixel power line MVDDL, only the second layer MVDDL1b of the first mesh pixel power line MVDDL1 can extend. The pixel power line VDDL of the pixel block PB can be formed of a single layer and can be formed in the same layer as the second layer MVDDL1b of the first mesh pixel power line MVDDL1, but is not limited thereto. The pixel power line VDDL of the pixel block PB can be formed of a double layer like the first mesh pixel power line MVDDL1.

The mesh common power line MVSSL of the mesh block MB can be electrically connected to the common power line VSSL of the pixel block PB. The mesh common power line MVSSL can be directly connected to the common power line VSSL of the pixel block PB. Alternatively, the mesh common power line MVSSL can be connected to the common power line VSSL of the pixel block PB through the dummy block DB.

In the mesh common power line MVSSL, the first mesh common power line MVSSL1 can extend in the first direction (for example, the Y-axis direction) toward the display area DA and can be connected to the common power line VSSL of the pixel block PB at one end thereof. In this case, the common power line VSSL of the pixel block PB cannot have a mesh structure, and thus, in the mesh common power line MVSSL, only the second layer MVSSL1b of the first mesh common power line MVSSL1 can extend. The common power line VSSL of the pixel block PB can be formed of a single layer and can be formed in the same layer as the second layer MVSSL1b of the first mesh common power line MVSSL1, but is not limited thereto. The common power line VSSL of the pixel block PB can be formed of a double layer like the first mesh common power line MVSSL1.

Furthermore, the mesh block MB can further include a scan line which extends in the second direction (for example, the X-axis direction) in the second non-transmissive area NTA2. The scan line can include a first scan line SCANL1 and a second scan line SCANL2. The mesh block MB can further include an emission control line EML which extends in the second direction (for example, the X-axis direction) in the second non-transmissive area NTA2. Each of the first scan line SCANL1, the second scan line SCANL2, and the emission control line EML can extend from the gate driver 205 and can extend up to pixel blocks PB of the display area DA.

In the mesh block MB, as illustrated in FIGS. 7 to 10, a color filter CF can be provided on the encapsulation layer 180. In the color filter CF, like the pixel block PB, each of a first color filter, a second color filter, and a third color filter can be patterned and formed. The first color filter can be disposed at a position corresponding to the first subpixel SP1 (see FIG. 3) of the pixel block PB and can be a blue color filter which transmits blue light. The second color filter can be disposed at a position corresponding to the second subpixel SP2 (see FIG. 3) of the pixel block PB and can be a red color filter which transmits red light. The third color filter can be disposed at a position corresponding to the third subpixel SP3 (see FIG. 3) of the pixel block PB and can be a green color filter which transmits green light.

Moreover, a black matrix BM can be provided between color filters CF and between the second transmissive area TA2 and the color filter CF.

In the transparent display panel 110 according to an embodiment of the present disclosure, the color filter CF and the black matrix BM can be included in the mesh block MB, and thus, the display area DA where the pixel block PB is disposed and the bezel area BA where the mesh block MB is disposed can have similar visibility.

Referring again to FIG. 2, a plurality of dummy blocks DB, a plurality of mesh blocks MB can be disposed between the display area DA and the mesh block MB. A plurality of dummy blocks DB can be provided between the pixel block PB and the mesh block MB. Each of the plurality of dummy blocks DB can include a third non-transmissive area where a plurality of dummy pixels are disposed and a third transmissive area where a plurality of dummy pixels are not disposed.

The dummy block DB can have the same size as that of the pixel block PB. Also, a ratio of a size of the third transmissive area in each dummy block DB to a size of an area of each dummy block DB can be equal to a ratio of a size of the first transmissive area TA1 in each pixel block PB to a size of an area of each pixel block PB. Accordingly, the transmissive display panel 110 according to an embodiment of the present disclosure can have the same light transmittance in a region where the pixel blocks PB are provided, a region where the dummy block DB is provided, and a region where the mesh blocks MB are provided. The transmissive display panel 110 according to an embodiment of the present disclosure can increase a light transmittance of an entire panel and can prevent the occurrence of a sense of difference between a region where the pixel blocks PB are provided, a region where the dummy block DB is provided, and a region where the mesh blocks MB are provided. For example, the transmissive display panel 110 according to an embodiment of the present disclosure can prevent the occurrence of a sense of difference between the display area DA and the bezel area BA.

A plurality of dummy pixels can be disposed in the third non-transmissive area and cannot transmit light incident from the outside. The pixel block PB can include a plurality of subpixels SP1 to SP3 (see FIG. 3) which emit light of a certain color, but the dummy block DB can include a plurality of dummy pixels which do not emit light.

The dummy pixel, like the subpixel, can include electrode patterns configuring a circuit device and electrode patterns and an emission layer configuring a light emitting device, but a contact hole for an electrical connection between the electrode patterns cannot be formed. For example, the first electrode E1 (see FIG. 5), the emission layer EL (see FIG. 5), and the second electrode E2 (see FIG. 5) of the light emitting device ED (see FIG. 5) included in the subpixels SP1 to SP3 (see FIG. 3) can be patterned and formed in the dummy pixel. However, because a contact hole is not formed in the dummy pixel, the first electrode E1 (see FIG. 5) cannot be electrically connected to the driving transistor DT. Accordingly, in the dummy pixel, the emission layer EL (see FIG. 5) provided between the first electrode E1 (see FIG. 5) and the second electrode E2 (see FIG. 5) cannot emit light.

In the dummy block DB, like the pixel block PB, first signal lines and second signal lines can be further disposed in a third non-transmissive area. The first signal line can extend in the first direction (for example, the Y-axis direction) in the third non-transmissive area. The first signal lines can include a pixel power line VDDL, a data line, and a common power line VSSL. In an embodiment, the first signal lines can further include a reference line.

The pixel power line VDDL and the common power line VSSL can be disposed apart from each other with the third transmissive area therebetween. The pixel power line VDDL included in the dummy block DB can extend from the pixel power line VDDL included in the pixel block PB, and one end thereof can be connected to a mesh pixel power line MVDDL included in the mesh block MB. The pixel power line VDDL included in the dummy block DB cannot transfer power to the dummy pixel.

The common power line VSSL included in the dummy block DB can extend from the common power line VSSL included in the pixel block PB, and one end thereof can be connected to the mesh common power line MVSSL included in the mesh block MB. The common power line VSSL included in the dummy block DB cannot transfer a second power to the dummy pixel.

The second signal lines can extend in the second direction (for example, the X-axis direction) in the third non-transmissive area. The second signal line can include a scan line SCANL. The scan line SCANL can include a first scan line and a second scan line. The second signal line SL2 can further include an emission control line. The scan line SCANL and the emission control line included in the dummy block DB can extend from the scan line SCANL and the emission control line included in the pixel block PB, and one end thereof can be connected to each of the scan line SCANL and the emission control line included in the mesh block MB. The scan line SCANL and the emission control line included in the dummy block DB cannot transfer a scan signal and an emission control signal.

The dummy block DB, like the pixel block PB, can include a color filter CF and a black matrix BM. Therefore, in the transparent display panel 110 according to an embodiment of the present disclosure, the display area DA where the pixel block PB is disposed and the bezel area BA where the dummy block DB and the mesh block MB are disposed can have similar visibility.

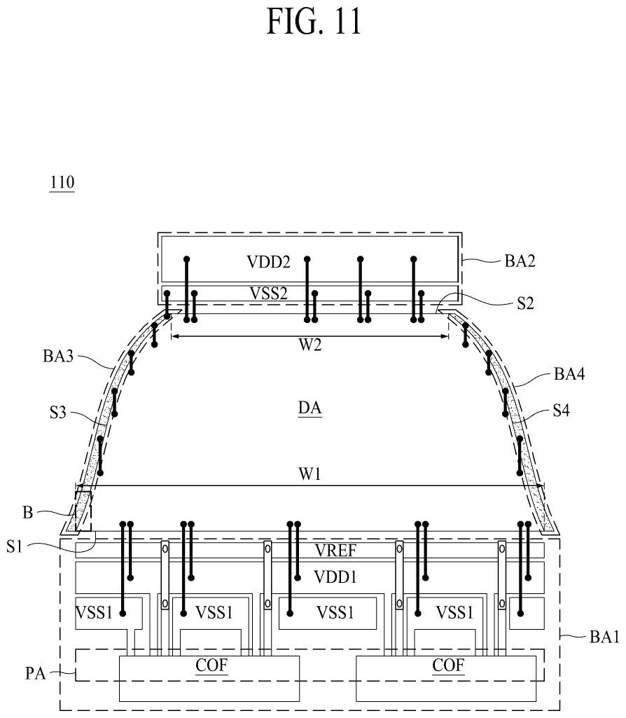

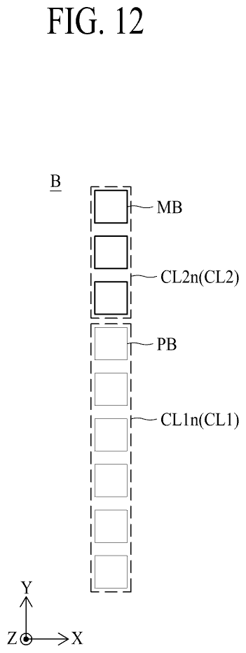

FIG. 11 is a diagram illustrating an example where a mesh block is disposed in a transparent display panel 110 according to an embodiment of the present disclosure. FIG. 12 is a diagram illustrating an example of a first column line and a second column line disposed in a region B of FIG. 11.

Referring to FIG. 11, the transparent display panel 110 according to an embodiment of the present disclosure can include a display area DA and a bezel area BA. The display area DA can include a first side S1 facing a pad area PA where power pads are provided, a second side S2 facing the first side S1, and a third side S3 and a fourth side S4 which connect the first side S1 to the second side S2.

In the display area DA, a width W1 of the first side S1 can differ from a width W2 of the second side S2. In an embodiment, in the display area DA, the width W1 of the first side S1 can be greater than the width W2 of the second side S2. As described above, in the display area DA, because the width W1 of the first side S1 differs from the width W2 of the second side S2, at least one of the third side S3 and the fourth side S4 can be inclined. When the width W1 of the first side S1 is greater than the width W2 of the second side S2, at least one of the third side S3 and the fourth side S4 can be inclined toward the first side S1. Alternatively, when the width W1 of the first side S1 is less than the width W2 of the second side S2, at least one of the third side S3 and the fourth side S4 can be inclined toward the second side S2. Hereinafter, for convenience of description, an example where the third side S3 and the fourth side S4 are inclined toward the first side S1 will be described, but embodiments of the present disclosure are not limited thereto. Only one of the third side S3 and the fourth side S4 can be inclined toward the first side S1.

A slope of each of the third side S3 and the fourth side S4 cannot be constant between the first side S1 and the second side S2. For example, a slope of each of the third side S3 and the fourth side S4 can vary toward the second side S2 from the first side S1.

A slope can vary based on the number of pixel blocks PB disposed in a column line. In detail, the display area DA can include a plurality of first column lines CL1 which are configured with pixel blocks PB arranged in the second direction (for example, the X-axis direction). First column lines CL1 disposed between the first side S1 and the second side S2 of the display area DA among a plurality of first column lines CL1 can include a same number of pixel blocks PB.

However, first column lines CL1 disposed between the first side S1 and the third side S3 and between the first side S1 and the fourth side S4 of the display area DA among the plurality of first column lines CL1 can include a different number of pixel blocks PB. The number of pixel blocks PB of the first column lines CL1 disposed between the first side S1 and the third side S3 of the display area DA can increase progressively toward a center region of the display area DA. The first column lines CL1 disposed between the first side S1 and the third side S3 of the display area DA can differ in variation of the number of pixel blocks PB toward the center region of the display area DA. In the first column lines CL1 disposed between the first side S1 and the third side S3 of the display area DA, a variation of the number of pixel blocks PB can decrease progressively toward the center region of the display area DA.

Moreover, the number of pixel blocks PB of the first column lines CL1 disposed between the first side S1 and the fourth side S4 of the display area DA can increase progressively toward the center region of the display area DA. The first column lines CL1 disposed between the first side S1 and the fourth side S4 of the display area DA can differ in variation of the number of pixel blocks PB toward the center region of the display area DA. In the first column lines CL1 disposed between the first side S1 and the fourth side S4 of the display area DA, a variation of the number of pixel blocks PB can decrease progressively toward the center region of the display area DA.

A slope can be determined based on a variation of the number of pixel blocks PB between adjacent first column lines CL1. When a variation of the number of pixel blocks PB between adjacent first column lines CL1 is large, the slopes of the third side S3 and the fourth side S4 can be large. On the other hand, when a variation of the number of pixel blocks PB between adjacent first column lines CL1 is small, the slopes of the third side S3 and the fourth side S4 can be small.

In the third side S3 of the display area DA, a variation of the number of pixel blocks PB disposed in the first column lines CL1 can decrease progressively toward the center region of the display area DA, and thus, a slope can decrease progressively toward the center region of the display area DA. Also, in the fourth side S4 of the display area DA, a variation of the number of pixel blocks PB disposed in the first column lines CL1 can decrease progressively toward the center region of the display area DA, and thus, a slope can decrease progressively toward the center region of the display area DA.

On the other hand, in the third side S3 of the display area DA, a variation of the number of pixel blocks PB disposed in the first column lines CL1 can increase progressively in a direction distancing from the center region of the display area DA, and thus, a slope can increase progressively in a direction distancing from the center region of the display area DA. Also, in the fourth side S4 of the display area DA, a variation of the number of pixel blocks PB disposed in the first column lines CL1 can increase progressively in a direction distancing from the center region of the display area DA, and thus, a slope can increase progressively in a direction distancing from the center region of the display area DA.

Moreover, the bezel area BA can include a first bezel area BA1 which is disposed at the first side S1 of the display area DA and includes the pad area PA, a second bezel area BA2 which is disposed at the second side S2 of the display area DA, a third bezel area BA3 which is disposed at the third side S3 of the display area DA, and a fourth bezel area BA4 which is disposed at the fourth side S4 of the display area DA.

A power pad, a first auxiliary common power electrode VSS1, a first auxiliary pixel power electrode VDD1, and an auxiliary reference power electrode VREF can be disposed in the first bezel area BA1. Each of the first auxiliary common power electrode VSS1, the first auxiliary pixel power electrode VDD1, and the auxiliary reference power electrode VREF can extend along the first side S1 of the display area DA and can be spaced apart from each other in the first bezel area BA1.

A second auxiliary common power electrode VSS2 and a second auxiliary pixel power electrode VDD2 can be disposed in the second bezel area BA2. Each of the second auxiliary common power electrode VSS2 and the second auxiliary pixel power electrode VDD2 can extend along the second side S2 of the display area DA and can be spaced apart from each other in the second bezel area BA2.

The first auxiliary pixel power electrode VDD1 can be connected to a pixel power pad disposed in the pad area PA and can be supplied with a first source voltage from a circuit film (a chip on film (COF)) through the pixel power pad. The first auxiliary pixel power electrode VDD1 can be connected to a pixel power line included in the display area DA and can supply the first source voltage to the pixel power line. One end of each of a plurality of pixel power lines included in the display area DA can be connected to the first auxiliary pixel power electrode VDD1, and the other end can be connected to the second auxiliary pixel power electrode VDD2. As described above, each of the plurality of pixel power lines can be connected to the first auxiliary pixel power electrode VDD1 and the second auxiliary pixel power electrode VDD2, and thus, can more uniformly and stably transfer the first source voltage.

The first auxiliary common power electrode VSS1 can be connected to a common power pad disposed in the pad area PA and can be supplied with a second source voltage from the circuit film (the COF) through the common power pad. The first auxiliary common power electrode VSS1 can be connected to a common power line included in the display area DA and can supply the second source voltage to the common power line. One end of each of a plurality of common power lines included in the display area DA can be connected to the first auxiliary common power electrode VSS1, and the other end can be connected to the second auxiliary common power electrode VSS2. As described above, each of the plurality of common power lines can be connected to the first auxiliary common power electrode VSS1 and the second auxiliary common power electrode VSS2, and thus, can more uniformly and stably transfer the second source voltage.

Furthermore, in the transparent display panel 110 according to an embodiment of the present disclosure, the width W1 of the first side S1 of the display area DA can be formed to be greater than the width W2 of the second side S2, and thus, pixel power lines and common power lines provided between the first side S1 and the third side S3 and between the first side S1 and the fourth side S4 cannot extend up to the second bezel area BA2. Therefore, the pixel power lines and the common power lines provided between the first side S1 and the third side S3 and between the first side S1 and the fourth side S4 cannot be connected to the second auxiliary pixel power electrode VDD2 and the second auxiliary common power electrode VSS2 provided in the second bezel area BA2. Also, the pixel power lines and the common power lines provided between the first side S1 and the third side S3 and between the first side S1 and the fourth side S4 can have a length which is shorter than that of each of pixel power lines and common power lines provided between the first side S1 and the second side S2. Therefore, the pixel power lines and the common power lines provided between the first side S1 and the third side S3 and between the first side S1 and the fourth side S4 can be less in resistance than the pixel power lines and the common power lines provided between the first side S1 and the second side S2. Particularly, the number of pixel blocks PB disposed in the first column line CL1 can largely decrease in a direction distancing from the center region of the display area DA, and thus, a length of each of the pixel power line and the common power line can be very short. Due to this, a voltage deviation between the pixel power lines included in the display area DA can increase, and a voltage deviation between the common power lines can increase, and thus, a luminance deviation can increase.

In the transparent display panel 110 according to an embodiment of the present disclosure, a plurality of mesh blocks MB can be disposed in the third bezel area BA3 and the fourth bezel area BA4, thereby decreasing a length difference between the pixel power lines and a length difference between the common power lines in the display area DA occurring due to a width difference between the first side S1 and the second side S2 of the display area DA. For example, in the transparent display panel 110 according to an embodiment of the present disclosure, the pixel power line and the common power line can extend up to the third bezel area BA3 and the fourth bezel area BA4 from the display area DA, and thus, a length of each of the pixel power lines and the common power lines provided between the first side S1 and the third side S3 and between the first side S1 and the fourth side S4 can increase.

Furthermore, in the transparent display panel 110 according to an embodiment of the present disclosure, the pixel power lines and the common power lines disposed in the third bezel area BA3 and the fourth bezel area BA4 can be connected to each other in a mesh form to form a mesh pixel power line and a mesh common power line, and thus, a voltage deviation between the pixel power lines provided in the display area DA can be reduced, and a voltage deviation between the common power lines can be reduced. Accordingly, the transparent display panel 110 according to an embodiment of the present disclosure can decrease a luminance deviation of the display area DA and can have uniform luminance.

Moreover, in the transparent display panel 110 according to an embodiment of the present disclosure, the number of mesh blocks MB disposed in a column line can vary based on a slope of each of the third side S3 and the fourth side S4 of the display area DA. In detail, the third bezel area BA3 and the fourth bezel area BA4 can include a plurality of second column lines CL2 configured with mesh blocks MB arranged in the second direction (for example, the X-axis direction).

Second column lines CL2 disposed at the third side S3 of the display area DA can respectively correspond to the first column lines CL1 disposed between the first side S1 and the third side S3 of the display area DA. For example, as illustrated in FIG. 12, an nth first column line CL1n can correspond to an nth second column line CL2n. A plurality of mesh blocks MB included in the nth second column line CL2n can be disposed on a plurality of pixel blocks PB included in the nth first column line CL1n.

When a slope of each of the third side S3 and the fourth side S4 of the display area DA is large, the number of mesh blocks MB included in the second column line CL2 can increase. On the other hand, when a slope of each of the third side S3 and the fourth side S4 of the display area DA is small, the number of mesh blocks MB included in the second column line CL2 can be small.

In the third side S3 of the display area DA, a variation of the number of pixel blocks PB disposed in the first column lines CL1 can decrease progressively toward the center region of the display area DA, and thus, a slope can decrease progressively toward the center region of the display area DA. Accordingly, in a second column line CL2 provided in the third bezel area BA3, the number of mesh blocks MB can decrease progressively toward the center region of the display area DA.

For example, the first column lines CL1 disposed between the first side S1 and the third side S3 of the display area DA can include one first column line CL1 having a first variation of the number of pixel blocks PB and another first column line CL1 having a second variation, which is less than the first variation, of the number of pixel blocks PB. In this case, a second column line CL2 corresponding to the other first column line CL1 can be less in number of mesh blocks MB than a second column line CL2 corresponding to the one first column line CL1.

Moreover, in the fourth side S4 of the display area DA, a variation of the number of pixel blocks PB disposed in the first column lines CL1 can decrease progressively toward the center region of the display area DA, and thus, a slope can decrease progressively toward the center region of the display area DA. Accordingly, in a second column line CL2 provided in the fourth bezel area BA4, the number of mesh blocks MB can decrease progressively toward the center region of the display area DA.

On the other hand, in the third side S3 of the display area DA, a variation of the number of pixel blocks PB disposed in the first column lines CL1 can increase progressively toward the center region of the display area DA, and thus, a slope can increase progressively toward the center region of the display area DA. Accordingly, in the second column line CL2 provided in the third bezel area BA3, the number of mesh blocks MB can increase progressively toward the center region of the display area DA.

Moreover, in the fourth side S4 of the display area DA, a variation of the number of pixel blocks PB disposed in the first column lines CL1 can increase progressively toward the center region of the display area DA, and thus, a slope can increase progressively toward the center region of the display area DA. Accordingly, in the second column line CL2 provided in the fourth bezel area BA4, the number of mesh blocks MB can increase progressively toward the center region of the display area DA.

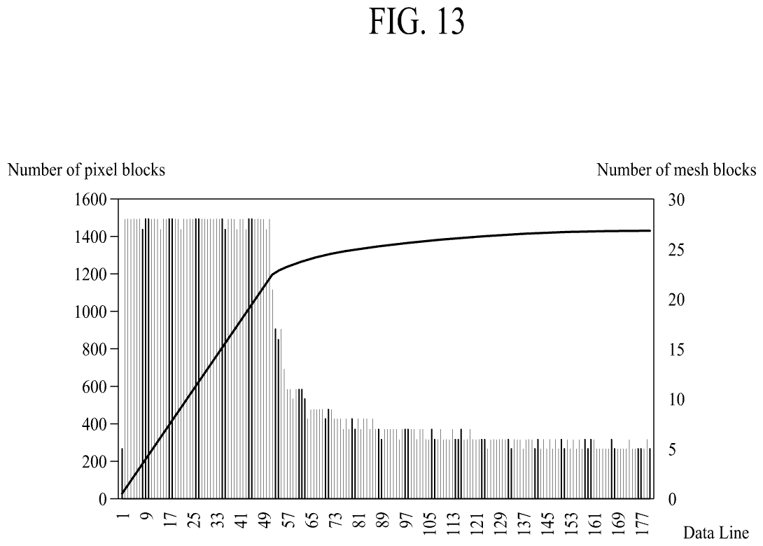

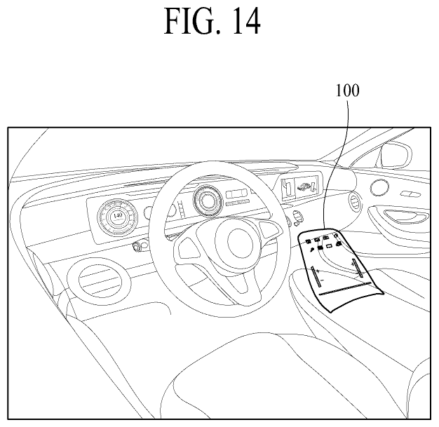

FIG. 13 is a graph showing a relationship between the number of pixel blocks included in a first column line and the number of mesh blocks included in a second column line.

A plurality of data lines can correspond to a plurality of first column lines and a plurality of second column lines. In this case, at least one data line can correspond to one first column line, based on a size of a pixel block PB. For example, one first column line can correspond to two data lines. A mesh block MB can have the same size as that of the pixel block PB, and thus, one second column line can correspond to two data lines. However, embodiments of the present disclosure are not limited thereto.

Referring to FIG. 13, in first column lines CL1, a variation of the number of pixel blocks PB can increase progressively toward a 49^{th} data line from a first data line, and then, in the first column lines CL1, a variation of the number of pixel blocks PB can decrease progressively toward a 177^{th} data line. In this case, a second column line CL2 corresponding to first column lines CL1 where a variation of the number of pixel blocks PB is large can include a number of mesh blocks MB within a range of 25 to 30 which is the number of mesh blocks MB.

Moreover, a second column line CL2 corresponding to first column lines CL1 where a variation of the number of pixel blocks PB is small can include only five mesh blocks MB as the number of mesh blocks MB is progressively reduced.

In the transparent display panel 110 according to an embodiment of the present disclosure, when a variation of the number of pixel blocks PB between adjacent first column lines CL1 is large, a number of mesh blocks MB can be provided, and thus, a length deviation of a pixel power line and a common power line between the adjacent first column lines CL1 can largely decrease. On the other hand, in the transparent display panel 110 according to an embodiment of the present disclosure, when a variation of the number of pixel blocks PB between adjacent first column lines CL1 is small, few mesh blocks MB can be provided, and thus, a length deviation of a pixel power line and a common power line between the adjacent first column lines CL1 can slightly decrease. Accordingly, the transparent display panel 110 according to an embodiment of the present disclosure can uniformly maintain a length deviation of a pixel power line and a common power line in an entire display area DA.

FIG. 14 is a diagram illustrating an example where a transparent display device 100 according to an embodiment of the present disclosure is applied to a vehicle.

Referring to FIG. 14, the transparent display device 100 can be installed at the inside of a vehicle and can display image information. For example, the transparent display device 100 can be installed between two front seats of the vehicle and can display vehicle control information or vehicle movement information.

In the present disclosure, like a pixel block included in a display area, a transmissive area can be included in a mesh block included in a bezel area, and thus, the display area and the bezel area can have the same light transmittance. The present disclosure can increase a light transmittance of an entire panel and can prevent the occurrence of a sense of difference between the display area and the bezel area.

Further, in the present disclosure, a color filter and a black matrix can be included in the mesh block, and thus, the display area where the pixel block is disposed and the bezel area where the mesh block is disposed can have similar visibility.

Moreover, in the present disclosure, a plurality of mesh blocks can be disposed in the bezel area, thereby decreasing a length deviation between common power lines and a length deviation between pixel power lines occurring due to a width difference between a lower portion and an upper portion of the display area. In the present disclosure, the pixel power line and the common power line included in the display area can extend up to a bezel area between the lower portion and the upper portion of the display area, thereby decreasing a length deviation between the pixel power lines and a length deviation between the common power lines.

Furthermore, in the present disclosure, pixel power lines and common power lines disposed in the bezel area can be connected to each other in a mesh form to form a mesh pixel power line and a mesh common power line, and thus, a voltage deviation between the pixel power lines can be reduced, and a voltage deviation between the common power lines can be reduced. Accordingly, the present disclosure can decrease a luminance deviation of the display area and can implement uniform luminance.

In addition, in the present disclosure, when a variation of the number of pixel blocks between adjacent first column lines is large, a number of mesh blocks can be provided, and thus, a length deviation of a pixel power line and a common power line between adjacent first column lines can largely decease. Also, in the present disclosure, when a variation of the number of pixel blocks between adjacent first column lines is small, few mesh blocks can be provided, and thus, a length deviation of a pixel power line and a common power line between adjacent first column lines can slightly decease. Accordingly, the present disclosure can uniformly maintain a length deviation of a pixel power line and a common power line in an entire display area.

The above-described features, structures, and effects of the present disclosure are included in at least one embodiment of the present disclosure, but are not limited to only one embodiment. Furthermore, the features, structures, and effects described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A transparent display device comprising:
a display area including a plurality of pixel blocks disposed therein, and configured to display an image;
a bezel area disposed at one or more sides of the display area; and
a plurality of mesh blocks disposed in the bezel area, each of the plurality of mesh blocks including a mesh power line having a mesh shape,
wherein each of the plurality of pixel blocks comprises a first transmissive area configured to transmit external light, and
wherein each of the plurality of mesh blocks comprises a second transmissive area configured to transmit external light.

2. The transparent display device of claim 1, wherein each of the plurality of pixel blocks has a same size as a size of at least one of the plurality of mesh blocks.

3. The transparent display device of claim 1, wherein a ratio of a size of the second transmissive area in each mesh block to a size of an area of each mesh block is equal to a ratio of a size of the first transmissive area in each pixel block to a size of an area of each pixel block.

4. The transparent display device of claim 1, wherein each of the plurality of pixel blocks comprises a power line provided in a first non-transmissive area to have a rectilinear shape, and
wherein each of the plurality of mesh blocks comprises the mesh power line provided in a second non-transmissive area.

5. The transparent display device of claim 4, wherein the power line of each pixel block comprises a pixel power line extending in a first direction and a common power line extending in the first direction, and
wherein the pixel power line and the common power line are disposed apart from each other with the first transmissive area therebetween.

6. The transparent display device of claim 5, wherein the pixel power line and the common power line are formed of a single layer.

7. The transparent display device of claim 4, wherein the mesh power line of each mesh block comprises a mesh pixel power line and a mesh common power line,
wherein the mesh pixel power line includes a first mesh pixel power line extending in a first direction and a second mesh pixel power line extending in a second direction, and
wherein the mesh common power line includes a first mesh common power line extending in the first direction and a second mesh common power line extending in the second direction.

8. The transparent display device of claim 7, wherein the first mesh pixel power line and the first mesh common power line are disposed apart from each other with the second transmissive area therebetween, and
wherein the second mesh pixel power line and the second mesh common power line are disposed apart from each other with the second transmissive area therebetween.

9. The transparent display device of claim 7, wherein the first mesh pixel power line and the first mesh common power line are formed of a plurality of layers, and
wherein the second mesh pixel power line and the second mesh common power line are formed of a single layer.

10. The transparent display device of claim 7, wherein the first mesh pixel power line is formed of a double layer in a region which does not overlap the second mesh common power line, and is formed of a single layer in a region overlapping the second mesh common power line, and
wherein the first mesh common power line is formed of a double layer in a region which does not overlap the second mesh pixel power line, and is formed of a single layer in a region overlapping the second mesh pixel power line.

11. The transparent display device of claim 7, wherein the power line of each pixel block comprises a pixel power line extending in the first direction and a common power line extending in the first direction, and
wherein the pixel power line of each pixel block is electrically connected to the mesh pixel power line of each mesh block, and the common power line of each pixel block is electrically connected to the mesh common power line of each mesh block.

12. The transparent display device of claim 1, further comprising a dummy block provided between a corresponding pixel block of the plurality of pixel blocks and a corresponding mesh block of the plurality of mesh blocks,
wherein each of the plurality of pixel blocks comprises a plurality of subpixels configured to emit light, and
wherein the dummy block comprises a plurality of dummy pixels configured to not emit light.

13. The transparent display device of claim 12, wherein the dummy block comprises a third transmissive area configured to transmit external light.

14. The transparent display device of claim 1, wherein the display area comprises a first side facing a pad area where a power pad is provided, a second side facing the first side, and a third side and a fourth side connecting the first side to the second side, and
wherein a width of the first side differs from a width of the second side in the display area.

15. The transparent display device of claim 14, wherein the width of the first side is greater than the width of the second side in the display area.

16. The transparent display device of claim 14, wherein the bezel area comprises:
a first bezel area disposed at the first side of the display area, the first bezel area including the pad area;
a second bezel area disposed at the second side of the display area;
a third bezel area disposed at the third side of the display area; and
a fourth bezel area disposed at the fourth side of the display area, and
wherein the plurality of mesh blocks are provided in at least one of the third bezel area and the fourth bezel area.

17. The transparent display device of claim 14, wherein at least one of the third side and the fourth side of the display area is inclined.

18. The transparent display device of claim 17, wherein a slope of at least one of the third side and the fourth side of the display area varies toward the second side of the display area from the first side of the display area.

19. The transparent display device of claim 14, wherein the display area comprises a plurality of first column lines each configured with pixel blocks arranged in a second direction, and
wherein among the plurality of first column lines, first column lines disposed between the first side and the third side of the display area differ in number of pixel blocks.

20. The transparent display device of claim 19, wherein, in the first column lines disposed between the first side and the third side of the display area, the number of pixel blocks increases progressively toward a center region of the display area, and variations of the number of pixel blocks differ.

21. The transparent display device of claim 19, wherein among the plurality of first column lines, each of first column lines disposed between the first side and the second side of the display area comprises a same number of pixel blocks.

22. The transparent display device of claim 21, wherein the bezel area comprises a plurality of second column lines each configured with mesh blocks arranged in the second direction, and
wherein among the plurality of second column lines, second column lines disposed at the third side of the display area respectively correspond to the first column lines disposed between the first side and the third side of the display area.

23. The transparent display device of claim 22, wherein the first column lines disposed between the first side and the third side of the display area comprise one first column line having a first variation of the number of pixel blocks and another first column line having a second variation, which is less than the first variation, of the number of pixel blocks, and
wherein a second column line corresponding to the another first column line is less in number of mesh blocks than a second column line corresponding to the one first column line.

24. The transparent display device of claim 1, wherein each of the plurality of pixel blocks comprises a power line provided in a first non-transmissive area, a light emitting device provided on the power line, and a color filter provided on the light emitting device, and
wherein each of the plurality of mesh blocks comprises the mesh power line provided in a second non-transmissive area and a color filter provided on the mesh power line.

25. The transparent display device of claim 13, wherein the dummy block has a same size as a size of the pixel block, and
wherein, a ratio of a size of the third transmissive area in each dummy block to a size of an area of each dummy block is equal to a ratio of a size of the first transmissive area in each pixel block to a size of an area of each pixel block.
